(19) United States
(12) Patent Application Publication
(10) Pub. No.: US 2006/0019032 A1
(43) Pub. Date: Jan. 26, 2006

(54) Low thermal budget silicon nitride formation for advance transistor fabrication

(76) Inventors: Yaxin Wang, Fremont, CA (US); Suryanarayanan Iyer, Santa Clara, CA (US); Sean Seutter, San Jose, CA (US)

Correspondence Address: PATTERSON & SHERIDAN, LLP, 3040 POST OAK BOULEVARD, SUITE 1500, HOUSTON, TX, 77056, US

(21) Appl. No.: 10/898,547

(22) Filed: Jul. 23, 2004

(51) Int. Cl. C23C 16/00

(52) U.S. Cl. 427/248.1

(57) ABSTRACT

In one embodiment, a method for depositing a layer containing silicon nitride on a substrate surface is provided which includes positioning a substrate in a process chamber, maintaining the substrate at a predetermined temperature, and exposing the substrate surface to an alkylaminosilane compound and at least one ammonia-free reactant. In another embodiment, a method for depositing a silicon nitride material on a substrate is provided which includes positioning a substrate in a process chamber, maintaining the substrate at a predetermined temperature, and exposing the substrate surface to bis(tertiarybutylamino)silane and a reagent, such as hydrogen, silane and/or disilane.

### BACKGROUND OF THE INVENTION

1. Field of the Invention

Embodiments of the invention generally relate to methods for depositing silicon-containing materials, more particularly, embodiments of the invention relate to chemical vapor deposition techniques for thermally depositing silicon nitride materials on substrate surfaces.

2. Description of the Related Art

Thermal chemical vapor deposition (CVD) of silicon nitride is the state of the art, in front-end process used during semiconductor device manufacturing. In a thermal-CVD process, thermal energy is utilized for breaking the feedstock chemical, typically a silicon precursor, to make a solid thin film on the substrate surface. Alternatively, a thermal-CVD process may activate two or more precursors including the silicon precursor to generate an atomically heterogeneous silicon-containing film during the fabrication of an advanced semiconductor device.

A deposition chamber equipped with a thermal source is used as a thermal deposition chamber for depositing silicon-containing materials. In particular, a batch furnace or a single wafer chamber operates at elevated temperatures typically above 500° C. Front-end processes, i.e., processes to fabricate functioning transistor, are generally conducted in a process chamber with thermal-CVD canabilities due to semiconductor device fabrication requirements, such as low metal contamination and stringent deposition attributes, such as consistent step coverage, minimum thickness variation from dense structure features to isolated features (termed as “pattern micro-loading”) and high film quality. Although, plasma enhanced-CVD (PE-CVD) processes are attractive means to deposit silicon-containing materials with low thermal budget, undesirably, the plasma ions may damage the active transistor regions of a device.

As electronic devices evolve to further miniaturization and increased performance, advanced device processing, specifically for <90 nm technology nodes, requires exposure to lower temperature processes for shorter time periods, i.e., lower thermal budget. In general, the temperature of a thermal process step performed in a subsequent step during a fabrication sequence should not be higher than a temperature of the prior process step, and thus maintain the overall designed device performance integrity. Silicon nitride films are generally formed through thermal processes and utilized during transistor formation as spacers for the isolation of gate materials and etch stop layers for source/drain and gate-poly contacts. As a spacer, the thermal budget during silicon nitride formation should be lower than thermal budget of a post-implant thermal anneal in order to maintain the integrity of activated doped material and to reduce short-channel leakage and channel mobility degradation. As an etch stop layer, the silicon nitride material usually requires a process temperature less than the temperature the contact+ silicide was previously processed, which currently is about 500° C. or less.

Traditionally, thermal CVD of silicon nitride utilizes silicon source precursors, such as silane (SiH₄), dichlorosilane (Cl₂SiH₂), disilane (Si₂H₆) or hexachlorodisilane (Si₂Cl₆), combined with a nitrogen source, such as ammonia (NH₃). These precursors and their process regime for the advanced semiconductor device requirements, particularly for the device generation 90 nm and below, cause significant disadvantages for future applications regardless of apparatus employed. Silane, dichlorosilane and ammonia have the fundamental limitations of low dissociation efficiency at temperatures below 600° C. due to the strong intermolecular bonds, therefore, are not production worthy precursors. Disilane and hexachlorodisilane have the weak Si—Si bond which allows for acceptable deposition rates at temperature below 550° C. However, when used with a nitrogen source such as ammonia below 550° C., the deposition rate is reduced due to a low dissociation rate of ammonia. Other available nitrogen precursors, such as the rather stable N₂ molecule, require a higher dissociation temperature. In addition, at a temperature less than 550° C., the film property may be poor and not desirable (e.g., low density and high hydrogen content) and poor performance (e.g., step coverage and micro-loading for disilane is worse than market accepted level). Also, chlorine based precursors (e.g., Cl₂SiH₂ or Si₂Cl₆) usually increase the chlorine content in the deposited materials. High chlorine content may cause defects or particle issues to process kits and may inhibit etch selectivity, which makes the film less useful for etch stop layer application.

Alternatively, the silicon precursor bis(tertiarybutylamino)silane (BTBAS or (^{t}Bu(H)N)₂SiH₂) may be used in thermal-CVD processes. However, BTBAS combined with ammonia has a slow deposition rate. For example, BTBAS/ammonia usually has a deposition rate of only a few Angstroms per minute at temperature below 550° C., which is not a production worthy process.

Conventional methods for forming silicon nitride as a sidewall structure often lead to deactivation of the semiconductor gate. The silicon nitride is traditionally formed at high temperatures to obtain a sufficient deposition rate. For example, conventional low pressure chemical vapor deposition (LPCVD) using dichlorosilane gas or BTBAS with ammonia for depositing silicon nitride requires a temperature of greater than 700° C. to maintain a sufficient silicon nitride deposition rate, such as a rate greater than 5 Å/min. The high temperature also imparts high activation energy to the dopants within extension regions of a device. The high activation energy causes the dopants to migrate in the grain boundaries of the dielectric material and/or the edges of the semiconductor gate. This migration causes dopant loss and subsequently, deactivation of the semiconductor gate with increased resistance of gate material.

In another example, silicon nitride material may be used as an etch stop layer while forming a metal contact via in the dielectric layer. Since a source/drain and gate silicide (e.g., nickel silicide) are formed at a temperature below 500° C., it is important to maintain the gate silicide integrity in order to ensure good metal to source/drain contact and metal to gate material contact while minimizing resistance increases or degradation. The increase of resistivity from the metal contact due to silicide degradation will cause higher power consumption and the excessive heat generation causes premature failure of a transistor.

Therefore, there is a need for a method of forming a desirable quality silicon nitride material using a deposition process at lower temperatures and capable of forming silicon nitride materials at manufacturable deposition rates.

### SUMMARY OF THE INVENTION

In one embodiment, a method for depositing a layer containing silicon nitride on a substrate surface is provided which includes positioning a substrate in a process chamber, maintaining the substrate at a predetermined temperature, exposing the substrate surface to an alkylaminosilane compound and at least one ammonia-free reactant, and depositing a silicon nitride material on the substrate surface.

In another embodiment, a method for depositing a silicon nitride material on a substrate is provided which includes maintaining the substrate at a temperature in a range from about 400° C. to about 650° C. within a process chamber, exposing the substrate to an alkylaminosilane compound and a reactant, such as hydrogen, silanes, boranes, germanes, alkyls, hydrocarbons, amines, hydrazines, derivatives thereof and combinations thereof.

In another embodiment, a method for depositing a silicon nitride material on a substrate is provided which includes positioning a substrate in a process chamber, maintaining the substrate at a predetermined temperature, and exposing the substrate surface to bis(tertiarybutylamino)silane and at least one ammonia-free reactant.

In another embodiment, a method for depositing a silicon nitride material on a substrate is provided which includes positioning a substrate in a process chamber, maintaining the substrate at a predetermined temperature, and exposing the substrate surface to bis(tertiarybutylamino)silane and hydrogen gas.

In another embodiment, a method for depositing a silicon nitride material on a substrate is provided which includes positioning a substrate in a process chamber, maintaining the substrate at a predetermined temperature, and exposing the substrate surface to bis(tertiarybutylamino)silane and silane or bis(tertiarybutylamino)silane and disilane.

In another embodiment, a method for forming a device on a substrate surface is provided which includes depositing a gate material and a silicon nitride material on a substrate, wherein the silicon nitride material is deposited with a process which includes positioning the substrate in a process chamber, maintaining the substrate at a predetermined temperature, and exposing the substrate surface to an ammonia-free process gas comprising an alkylaminosilane compound and at least one ammonia-free reactant.

In another embodiment, a method for depositing a silicon nitride material on a substrate is provided which includes positioning a substrate in a process chamber, maintaining the substrate at a predetermined temperature, and exposing the substrate surface to bis(tertiarybutylamino)silane and a hydrocarbon or an alkyl compound.

### BRIEF DESCRIPTION OF THE DRAWINGS

So that the manner in which the above recited features of the invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1B represent cross sections of typical a MOSFET translator having silicon nitride layers at least partially deposited thereon according to embodiments described herein;

FIG. 2 represents a cross section of typical bipolar transistor having silicon nitride layers at least partially deposited thereon according to embodiments described herein; and

FIG. 3 represents a graph illustrating various experiments of an embodiment described herein.

### DETAILED DESCRIPTION

Methods are disclosed in multiple embodiments to deposit silicon nitride materials on a substrate surface. The methods generally include exposing the substrate surface to a silicon precursor, such as an alkylaminosilane compound and at least one ammonia-free reactant. In a preferred embodiment, the silicon precursor is bis(tertiarybutylamino)silane (BTBAS), while the ammonia-free reactant may be a compound, such as hydrogen, silanes, boranes, germanes, alkyls, amines or hydrazines.

Silicon nitride materials may be deposited by several deposition techniques. Preferably, silicon nitride materials are formed by chemical vapor deposition (CVD) processes, such as thermal-CVD. Thermal-CVD processes deposit silicon nitride materials by co-flowing a silicon precursor and a reactant into a process chamber. The process chamber and/or the substrate are heated to a predetermined temperature to cause a chemical reaction between the reagents. Generally, the flow of the silicon precursor and the reactant is co-current and constant. However, increases or decreases of either reagent may be desirable depending on the preferred process. Besides traditional thermal-CVD, other useful processes to deposit silicon nitride materials include pulsed-CVD and atomic layer deposition (ALD). During a pulsed-CVD process, reagents, such as a silicon precursor and a reactant, are co-flowed and pulsed into the process chamber. Durina an ALD process, reagents, such as a silicon precursor and a reactant, are individually and sequentially pulsed into the process chamber. Plasma enhanced deposition techniques may be used during either ALD or CVD processes. Silicon nitride materials may be deposited to a single substrate or a batch of substrates during the deposition processes described herein.

A “substrate surface,” as used herein, refers to any substrate or material surface formed on a substrate upon which film processing is performed. For example, a substrate surface on which processing can be performed include, but not limited to, materials such as silicon, silicon oxide, strained silicon, silicon on insulator (SOI), germanium on insulator (GOI), carbon doped silicon oxides, silicon nitrides, silicon oxynitrides, doped silicon, germanium, gallium arsenide, glass, sapphire, and any other materials such as metals, metal nitrides, metal alloys, and other conductive materials, dependant on the specific application. Barrier layers, metals or metal nitrides on a substrate surface include titanium, titanium nitride, tungsten nitride, tantalum and tantalum nitride. Substrates may have various dimensions, such as 200 mm or 300 mm diameter wafers, as well as, rectangular or square panes. Embodiments of the processes described herein deposit silicon nitride materials on many substrates and surfaces. Substrates on which embodiments of the invention may be useful include, but are not limited to semiconductor wafers, such as crystalline silicon (e.g., Si<100> or Si<111>), silicon oxide, strained silicon, SOI, silicon germanium, doped or undoped polysilicon, doped or undoped silicon wafers silicon nitride and patterned or non-patterned wafers. Surfaces include bare silicon wafers, films, layers and materials with dielectric, conductive and barrier properties and include aluminum oxide, polysilicon and other gate materials. Pretreatment of surfaces prior to silicon nitride material deposition includes polishing, etching, reduction, oxidation, halogenation, hydroxylation, annealing and baking.

Throughout the application, the terms “silicon nitride” materials, compounds, films or layers should be construed to include a composition containing at least silicon and nitrogen and may include other elements. The silicon nitride materials formed and/or deposited during embodiments of the invention have a varied elemental concentration. Generally, silicon nitride is deposited as a layer or film with the empirical, chemical formula, SiNₓ. Fully nitrided silicon nitride may have the chemical formula Si₃N₄, such that the N:Si ratio (atomic) is about 1.33. However, less nitrided silicon nitride material may be formed with N:Si ratio as low as about 0.7. Therefore, silicon nitride materials have a N:Si ratio from about 0.7 to about 1.33, preferably, from about 0.8 to about 1.3. Silicon nitride materials may contain other elements, besides silicon and nitrogen, such as hydrogen, carbon, oxygen and/or boron. In some embodiments, the hydrogen concentration in the silicon nitride material is about 8 weight percent (wt %) or greater. The carbon concentration in the silicon nitride material may be from about 3 atomic percent (at %) to about 15 at %. Silicon nitride materials include silicon nitride (SiNₓ), silicon oxynitride (SiOₓN_{y}), silicon carbon nitride (SiCₓN_{y}), and silicon carbon oxynitride (SiCₓO_{y}N_{z}). Silicon nitride materials may be formed with varying stoichiometry and composition by controlling the process conditions described herein.

Process conditions are variable based on factors, such as desired composition of the silicon nitride material deposited, as well as placement in an electronic feature, particular silicon precursor or reactant used, and the multiplicity of substrates processed (e.g., single wafer or batch wafer depositions). The mixture of a silicon precursor and one or more reactant provides a lower deposition temperature without sacrificing film quality or rate of deposition. As such, good film qualities including reflective index and wet etch rate, and deposition rates greater than 5 Å/min. Preferably, the silicon nitride film is deposited at a rate from about 10 Å/min to about 500 Å/min, more preferably, from about 20 Å/min to about 200 Å/min, for example 100 Å/min. The silicon nitride layer typically has a thickness from about 10 Å to about 1,000 Å. For example, in one application, the silicon nitride layer typically has a thickness from about 100 Å to about 1,000 Å, while another application requires a thickness of about 50 Å or less.

The silicon nitride materials are usually deposited at a temperature from about 200° C. to about 800° C., preferably less than 700° C., such as from about 400° C. to about 650° C., for example 500° C. The process chamber may be a single wafer, low pressure thermal-CVD chamber, such as the SINGEN®, available from Applied Materials, Inc., located in Santa Clara, Calif. The processing chamber may be integrated into a multi-processing platform, such as a CENTURA® platform or the PRODUCER® platform, each available from Applied Materials, Inc., located in Santa Clara, Calif. Such processing platform is capable of performing several processing operations without breaking vacuum. In another embodiment, the silicon nitride material is deposited with an ALD process using the single wafer chamber described in commonly assigned U.S. patent application Ser. No. 10/032,284, entitled, “Gas Delivery Apparatus and Method for Atomic Layer Deposition,” filed on Dec. 21, 2001, which is incorporated by reference herein. The invention also anticipates conducting the process of depositing the silicon nitride material in a batch furnace chamber configured for CVD or ALD processes.

Generally, the silicon nitride deposition process is performed in a single wafer chamber at a pressure maintained from about 0.1 Torr to about 1,000 Torr, preferably, from about 10 Torr to about 760 Torr and more preferably from about 10 Torr to about 500 Torr, for example, 250 Torr. The silicon nitride deposition process may also be performed in batch furnace chamber at a pressure maintained from about 0.1 Torr to about 10.0 Torr, preferably, from about 0.3 Torr to about 1.0 Torr, for example, 0.5 Torr. A flow gas and/or a purge gas is administered into the process chamber throughout various steps of the deposition process, Usually, the flow gas and/or purge gas has a flow rate from about 100 sccm to about 3,000 sccm, depending on the process chamber design and reagents utilized during the deposition process. A flow gas and/or purge gas may be argon, helium, nitrogen, hydrogen, forming gas and combinations thereof. In one embodiment, a plasma maybe struck with or without the flow gas, but preferably contains argon and/or nitrogen.

In one embodiment, a silicon precursor and a reactant are co-flowed into the process chamber during a single wafer, thermal-CVD process for depositing silicon nitride materials. The silicon precursor is administered into the process chamber with a flow rate from about 1 sccm to about 300 sccm, preferably from about 1 sccm to about 100 sccm. For example, BTBAS may have a flow rate from about 13 sccm to about 130 sccm, which is equivalent to a rate from about 0.1 g/min to about 1.0 g/min when combined with a carrier gas. The reactant is administered into the process chamber with a flow rate from about 100 sccm to about 3,000 sccm, preferably from about 500 sccm to about 3,000 sccm, and more preferably, from about 1,000 sccm to about 2,000 sccm. The reactant flow rate or concentration may vary relative to the flow rate or concentration of the silicon precursor. During the CVD of single wafer processes, a reactant/silicon precursor molar ratio (e.g., H₂/BTBAS or SiH₄/BTBAS) is at least about 10, preferably from about 10 to about 100, for example, from about 30 to about 50.

In another embodiment, a silicon precursor and a reactant are co-flowed into the process chamber during a batch wafer, thermal-CVD process for depositing silicon nitride materials. The silicon precursor is administered into the process chamber with a flow rate from about 1 sccm to about 300 sccm, preferably from about 1 sccm to about 100 sccm. Once the base pressure is constant, the reactant is administered into the process chamber with a flow rate from about 100 sccm to about 3,000 sccm, preferably from about 500 sccm to about 1,000. The reactant flow rate or concentration may vary relative to the flow rate or concentration of the silicon precursor, batch chamber volume and the number of wafer to be processed. During the CVD of batch wafer processes, a reactant/silicon precursor molar ratio (e.g., H₂/BTBAS or SiH₄/BTBAS) is usually less than 30, preferably less than 20, more preferably, less than 10, for example, about 8. Although the reactant/silicon precursor molar ratio for batch wafer CVD processes is usually less than 30, some embodiments anticipate a higher ratio, such as about 100.

In another embodiment, the silicon precursor and the reactant are sequentially pulsed into the process chamber during ALD processes to deposit silicon nitride materials. The silicon precursor is administered into the process chamber with a flow rate from about 1 sccm to about 300 sccm, preferably from about 10 sccm to about 100 sccm. For example, BTBAS may have a flow rate from about 13 sccm to about 130 sccm, which is equivalent to a rate from about 0.1 g/min to about 1.0 g/min depending on the BTBAS partial pressure and the exposed surface area. The reactant is administered into the process chamber with a flow rate from about 100 sccm to about 3,000 sccm or higher, preferably greater than about 500 sccm, such as from about 500 sccm to about 3,000, more preferably, from about 1,000 sccm to about 2,000 sccm.

Generally, an ALD process cycle includes pulsing a silicon precursor, exposing the process chamber to a purge gas, pulsing a reactant, and exposing the process chamber to the purge gas. The cycle is repeated until the silicon nitride material is deposited to a predetermined thickness. The pulses of silicon precursor, reactant or purge gas independently have a time duration from about 0.05 seconds to about 10 seconds, preferably from about 0.1 seconds to about 1 second, for example, about 0.5 seconds.

“Atomic layer deposition” or “cyclical deposition” as used herein refers to the sequential introduction of two or more reactive compounds to deposit a layer of material on a substrate surface. The two, three or more reactive compounds may alternatively be introduced into a reaction zone of a process chamber. Usually, each reactive compound is separated by a time delay to allow each compound to adhere and/or react on the substrate surface. In one aspect, a first precursor or compound A (e.g., silicon precursor) is pulsed into the reaction zone followed by a first time delay. Next, a second precursor or compound B (e.g., reactant) is pulsed into the reaction zone followed by a second delay. During each time delay a purge gas, such as nitrogen, is introduced into the processing chamber to purge the reaction zone or otherwise remove any residual reactive compound or by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, pulsing compound B and purge gas is a cycle. A cycle can start with either compound A or compound B and continue the respective order of the cycle until achieving a film with the desired thickness.

A silicon nitride material is deposited by chemical methods from a silicon precursor. The silicon precursor generally contains nitrogen, such as an aminosilane. Specific aminosilanes that are useful silicon precursors are alkylaminosilanes with the chemical formula of (RR′N)₄₋ₙSiHₙ, wherein R and R′ are independently hydrogen, methyl, ethyl, propyl, butyl, pentyl or aryl and n=0, 1, 2 or 3. In one embodiment, R is hydrogen and R′ is an alkyl group, such as methyl, ethyl, propyl, butyl or pentyl, for example, R′ is a butyl group, such as tertiarybutyl and n is 2. In another embodiment, R and R′ are independently alkyl groups, such as methyl, ethyl, propyl, butyl and pentyl or an aryl group. Silicon precursors useful for the deposition processes described herein include (^{t}Bu(H)N)₃SiH, (^{t}Bu(H)N)₂SiH₂, (^{t}Bu(H)N)SiH₃, (ⁱPr(H)N)₃SiH, (ⁱPr(H)N)₂SiH₂, (ⁱPr(H)N)SiH₃, and derivatives thereof. Preferably, the silicon precursor is bis(tertiarybutylamino)silane ((^{t}Bu(H)N)₂SiH₂ or BTBAS). In other embodiments, the silicon precursor may be an alkylaminosilane with the chemical formula of (RR′N)₄₋ₙSiR″ₙ, wherein R and R′ are independently hydrogen, methyl, ethyl, propyl, butyl, pentyl, or aryl, R″ is independently hydrogen, alkyl (e.g., methyl, ethyl, propyl, butyl or pentyl), aryl or halogen (e.g., F, Cl, Br or I) and n=0, 1, 2 or 3.

The chemical deposition of silicon nitride materials may be achieved by chemically reducing the silicon precursor with a reactant, preferably, an ammonia-free reactant. A reactant chemically reduces (i.e., transfers electrons) during a reaction between two molecules. Although the silicon precursor, namely an alkylaminosilane, may thermal decompose in the absence of a reactant to form a silicon nitride material, the reactant benefits the reaction by increasing the deposition rate, even at lower temperatures. Not to be bound or limited to specific theories or mechanisms, it is believed that a reactant aids the reaction by reducing the alkyl functional group from the alkylamino group in the alkylaminosilane, for example, forming isobutylene and/or tertbutylamine from BTBAS.

Reactants that may be used in the deposition processes described herein include hydrogen (H₂), silanes, germanes, boranes, hydrocarbons and/or alkyls, phosphines, amines, hydrazines, azides, derivatives thereof and combinations thereof. Silanes include silane (SiH₄), disilane (Si₂H₆), trisilane (Si₃H₈), dichlorosilane (Cl₂SiH₂), hexachlorodisilane (Si₂Cl₆), alkylsilanes (e.g. MeSiH₃) and derivatives thereof. Germanes include germane (GeH₄), digermane (Ge₂H₆), trigermane (Ge₃H₈), alkylgermanes (e.g., MeGeH₃) and derivatives thereof. Boranes include borane (BH₃), diborane (B₂H₆) and alkylboranes (e.g., Et₃B), adducts thereof and derivatives thereof. Hydrocarbons and/or alkyls include methane (CH₄), ethane (C₂H₆), propane (C₃H₈), butane (C₄H₁₀), ethene (C₂H₄), ethyne (C₂H₂), propene (C₃H₆), propyne (C₃H₄), butane (C₄H₈), butyne (C₄H₆) and derivatives thereof. Phosphines include phoshine (PH₃), methylphosphine (MePH₂), dimethylphosphine (Me₂PH) and derivatives thereof. Amines and hydrazines include (H₃Si)₃N, (Me₃Si)₃N, Me₃N, Et₃N, H₂NNH₂, Me(H)NNH₂, Me₂NNH₂, Me₂NNMe₂, ^{t}BuNN^{t}Bu, and derivatives thereof. In a preferred embodiment, the reactant is hydrogen, silane, disilane or combinations thereof.

In some embodiments, an oxygen precursor may be added to a deposition process that includes the silicon precursor and the reactant to form silicon oxide or a silicon nitride material, such as silicon oxynitride. Oxygen precursors that may be used in the deposition processes described herein include atomic-O, oxygen (O₂), ozone (O₃), H₂O, H₂O₂, organic peroxides, alcohols, N₂O, NO, NO₂, N₂O₅, derivatives thereof and combinations thereof.

Silicon nitride materials are deposited throughout electronic features/devices due to several physical properties. Silicon nitride materials are electric insulators, as well as barrier materials. The barrier properties inhibit ion diffusion between dissimilar materials or elements when silicon nitride material is placed therebetween, such as a gate material and an electrode. Therefore, silicon nitride materials may be used in barrier layers, protective layers, off-set layers, spacer layers and capping layers. Another physical property of silicon nitride materials is a high degree of hardness. In some applications, silicon nitride materials may be used as a protective coating for various optical devices as well as tools. Yet another physical property of silicon nitride is etch selectivity to silicon oxide, i.e., silicon nitride can be used as etch stop layer under a silicon oxide dielectric layer to accurately control etch depth without over etching or under etching.

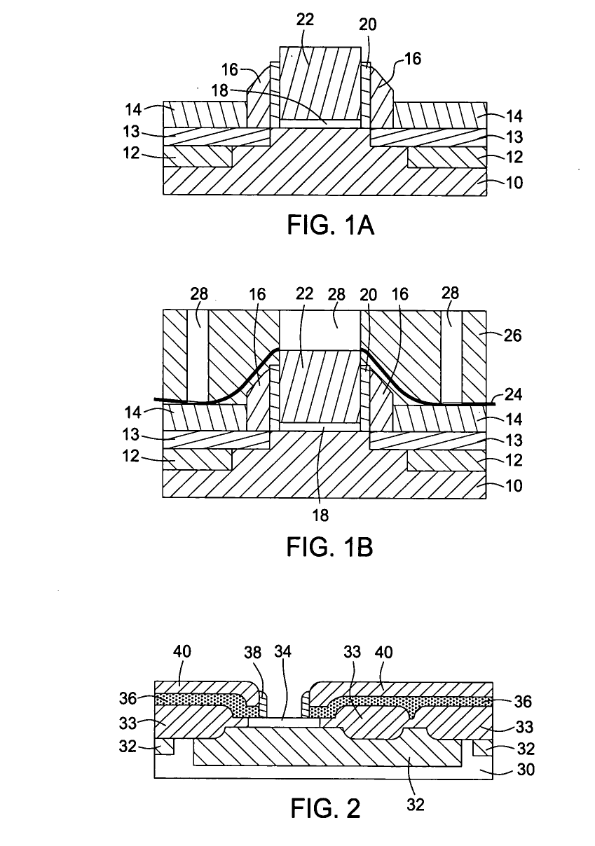

In some embodiments, silicon nitride materials may be deposited as various layers in MOSFET and bipolar transistors as depicted in FIGS. 1A-2. FIG. 1A shows silicon nitride materials deposited within a MOSFET containing both recessed and elevated source/drains. Source/drain layer 12 is formed by ion implantation of the substrate 10. Generally, the substrate 10 is doped n-type while the source/drain layer 12 is doped p-type. Silicon-containing layer 13, usually Si, SiGe or SiGeC, is selectively and epitaxially grown on the source/drain layer 12 or directly on substrate 10 by CVD methods. Silicon-containing layer 14 is also selectively and epitaxially grown on the silicon-containing layer 13 by CVD methods. A gate barrier layer 18 bridges the segmented silicon-containing layer 13. Generally, gate barrier layer 18 maybe composed of silicon oxide, silicon oxynitride or hafnium oxide. Partially encompassing the gate barrier layer 18 is a spacer 16, which is usually an isolation material such as a nitride/oxide/nitride stack (e.g., Si₃N₄/SiO₂/Si₃N₄). Alternatively, spacer 16 may be a homogeneous layer of a silicon nitride material, such as silicon nitride or silicon oxynitride deposited by the various processes described herein. Gate layer 22 (e.g., polysilicon) may have a spacer 16 and off-set layers 20 disposed on either side. Off-set layers 20 may be composed of a silicon nitride material, such as silicon nitride, deposited by the various processes described herein.

FIG. 1B shows etch stop layer 24 for source/drain and gate contact via etch deposited over a MOSFET. Etch stop layer 24 may be composed of a silicon nitride material, such as silicon nitride, deposited by the various processes described herein. A pre-metal dielectric layer 26 (e.g., silicon oxide) is deposited on etch stop layer 24 and contains contact hole vias 28 formed thereon.

In another embodiment, FIG. 2 depicts deposited silicon nitride material as several layers within a bipolar transistor during various embodiments of the invention. The silicon-containing compound layer 34 is deposited on an n-type collector layer 32 previously deposited on substrate 30. The transistor further includes isolation layer 33 (e.g., SiO₂, SiOₓN_{y} or Si₃N₄), contact layer 36 (e.g., heavily doped poly-Si), off-set layer 38 (e.g., Si₃N₄), and a second isolation layer 40 (e.g., SiO₂, SiOₓN_{y} or S₃N₄). Isolation layers 33 and 40 and off-set layer 38 may be independently deposited as a silicon nitride material, such as silicon oxynitride, silicon carbon nitride, and/or silicon nitride deposited by the various processes described herein. Preferably, isolation layers 33 and 40 are silicon oxynitride and off-set layer 38 is silicon nitride.

### COMPARATIVE EXAMPLE

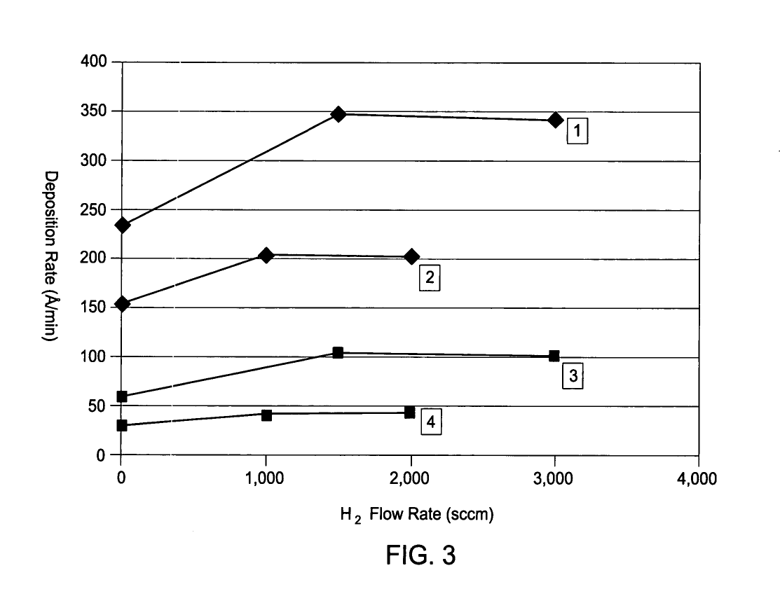

FIG. 3 shows several comparison examples of the deposition of silicon nitride materials with BTBAS by thermal-CVD processes. The comparison demonstrates that a reactant, such as hydrogen gas, increases the deposition rate of silicon nitride material with or without ammonia. In fact, the use of ammonia as a reactant tends to inhibit the formation of silicon nitride material with BTBAS and hydrogen.

Runs 1 and 2 were conducted at 650° C., while Runs 3 and 4 were conducted at 600° C. Runs 1 and 3 contained no ammonia, while Runs 2 and 4 were conducted with an ammonia flow rate of 1,000 sccm. For Run 1, the rate of silicon nitride material deposition was determined to be 234 Å/min, 348 Å/min and 342 Å/min, corresponding to a hydrogen flow rate of 0 sccm, 1,500 sccm and 3,000 sccm, respectively. For Run 2, the rate of silicon nitride material deposition was determined to be 153 Å/min, 203 Å/min and 202 Å/min, corresponding to a hydrogen flow rate of 0 sccm, 1,000 sccm and 2,000 sccm, respectively. When the deposition process was with hydrogen, BTBAS thermally decomposed to form the silicon nitride material about 53% faster than when ammonia was present. Therefore, ammonia seems to interfere with the formation of silicon nitride. However, when hydrogen was administered with ammonia, the deposition rate increased, though not as fast as the process absent ammonia (See the second and third data points during Runs 1 and 2.).

For Run 3, the rate of silicon nitride material deposition was determined to be 60 Å/min, 106 Å/min and 103 Å/min, corresponding to a hydrogen flow rate of 0 sccm, 1,500 sccm and 3,000 sccm, respectively. For Run 4, the rate of silicon nitride material depositon was determined to be 30 Å/min; 43 Å/min and 43 Å/min, corresponding to a hydrogen flow rate of 0 sccm, 1,000 sccm and 2,000 sccm, respectively. Runs 3 and 4 correlate well with Runs 1 and 2, but with slower deposition rates due to the lower temperature. Overall, the addition of a reactant, such as hydrogen gas, to a deposition process containing BTBAS for depositing silicon nitride materials, increases the deposition rate at temperatures otherwise not favorable for silicon nitride formation. The second and third data point of Run 3 demonstrates that even at 600° C., silicon nitride material is deposited at a rate of more than 100 Å/min.

### EXAMPLES

The following hypothetical examples are to better demonstrate the attributes to the various embodiments herein. The examples should not be construed in any limiting scope of the invention. During Examples 1-6, the CENTURA® 300 mm SINGEN® low pressure, thermal-CVD chamber, available from Applied Materials, Inc., was used during single wafer processes. During Examples 7-12, a thermal-CVD chamber/furnace for batch wafer processes was used. During Examples 13-18, a 300 mm ALD chamber by Applied Materials, Inc., was used during single wafer ALD processes.

### Example 1

A 300 mm substrate has placed into the process chamber and maintained at about 550° C. at a pressure of about 250 Torr. A process gas containing hydrogen gas (H₂) with a flow rate of about 2,000 sccm and BTBAS ((^{t}Bu(H)N)₂SiH₂) with a flow rate of about 50 sccm was exposed to the substrate surface. A silicon nitride material was deposited at a rate of about 60 Å/min for about 5 minutes to produce a film with a thickness about 300 Å.

### Example 2

A 300 mm substrate has placed into the process chamber and maintained at about 475° C. at a pressure of about 450 Torr. A process gas containing silane (SiH₄) with a flow rate of about 1,000 sccm and BTBAS with a flow rate of about 30 sccm was exposed to the substrate surface. A silicon nitride material was deposited at a rate of about 50 Å/min for about 5 minutes to produce a film with a thickness about 250 Å.

### Example 3

A 300 mm substrate has placed into the process chamber and maintained at about 425° C. at a pressure of about 450 Torr. A process gas containing disilane (Si₂H₆) with a flow rate of about 1,000 sccm and BTBAS with a flow rate of about 25 sccm was exposed to the substrate surface. A silicon nitride material was deposited at a rate of about 40 Å/min for about 5 minutes to produce a film with a thickness about 200 Å.

### Example 4

A 300 mm substrate has placed into the process chamber and maintained at about 550° C. at a pressure of about 550 Torr. A process gas containing methane gas (CH₄) with a flow rate of about 3,000 sccm and BTBAS with a flow rate of about 100 sccm was exposed to the substrate surface. A silicon nitride material was deposited at a rate of about 50 Å/min for about 6 minutes to produce a film with a thickness about 300 Å and contained about 10 at % carbon.

### Example 5

A 300 mm substrate has placed into the process chamber and maintained at about 450° C. at a pressure of about 450 Torr. A process gas containing germane (GeH₄) with a flow rate of about 1,000 sccm and BTBAS with a flow rate of about 25 sccm was exposed to the substrate surface. A silicon nitride material was deposited at a rate of about 40 Å/min for about 5 minutes to produce a film with a thickness about 200 Å.

### Example 6

A 300 mm substrate has placed into the process chamber and maintained at about 475° C. at a pressure of about 500 Torr. A process gas containing diborane (B₂H₆) with a flow rate of about 1,500 sccm and BTBAS with a flow rate of about 35 sccm was exposed to the substrate surface. A silicon nitride material was deposited at a rate of about 40 Å/min for about 5 minutes to produce a film with a thickness about 200 Å.

### Example 7

A 300 mm substrate has placed into a batch-process chamber and maintained at about 500° C. at a pressure of about 0.5 Torr. A process gas containing hydrogen gas with a flow rate of about 200 sccm and BTBAS with a flow rate of about 15 sccm was exposed to the substrate surface. A silicon nitride material was deposited at a rate of about 10 Å/min for about 25 minutes to produce a film with a thickness about 250 Å.

### Example 8

A 300 mm substrate has placed into a batch process chamber and maintained at about 450° C. at a pressure of about 0.7 Torr. A process gas containing silane with a flow rate of about 100 sccm and BTBAS with a flow rate of about 15 sccm was exposed to the substrate surface. A silicon nitride material was deposited at a rate of about 5 Å/min for about 40 minutes to produce a film with a thickness about 200 Å.

### Example 9

A 300 mm substrate has placed into a batch process chamber and maintained at about 450° C. at a pressure of about 0.5 Torr. A process gas containing disilane with a flow rate of about 100 sccm and BTBAS with a flow rate of about 12 sccm was exposed to the substrate surface. A silicon nitride material was deposited at a rate of about 10 Å/min for about 30 minutes to produce a film with a thickness about 300 Å.

### Example 10

A 300 mm substrate has placed into a batch process chamber and maintained at about 600° C. at a pressure of about 1.0 Torr. A process gas containing methane gas with a flow rate of about 300 sccm and BTBAS with a flow rate of about 20 sccm was exposed to the substrate surface. A silicon nitride material was deposited at a rate of about 10 Å/min for about 30 minutes to produce a film with a thickness about 300 Å.

### Example 11

A 300 mm substrate has placed into a batch process chamber and maintained at about 450° C. at a pressure of about 0.5 Torr. A process gas containing germane with a flow rate of about 100 sccm and BTBAS with a flow rate of about 10 sccm was exposed to the substrate surface. A silicon nitride material was deposited at a rate of about 20 Å/min for about 20 minutes to produce a film with a thickness about 400 Å.

### Example 12

A 300 mm substrate has placed into a batch process chamber and maintained at about 475° C. at a pressure of about 0.7 Torr. A process gas containing diborane with a flow rate of about 150 sccm and BTBAS with a flow rate of about 20 sccm was exposed to the substrate surface. A silicon nitride material was deposited at a rate of about 20 Å/min for about 20 minutes to produce a film with a thickness about 400 Å.

### Example 13

A 300 mm substrate has placed into the process chamber and maintained at about 550° C. at a pressure of about 10 Torr. A flow of process gas containing Ar (2,000 sccm) and BTBAS (25 sccm) was pulsed into the process chamber for 0.5 seconds. A layer of BTBAS was adsorbed to the substrate and the chamber was purged for 1 second to remove excess process gas. Hydrogen gas (3,000 sccm) was exposed to the substrate surface for 1 second. The BTBAS adsorbed to the substrate was chemically reduced to form a silicon nitride material on the substrate surface. The chamber was purged for 1 second to remove excess gasses, by-products and contaminates. The silicon nitride material was deposited at a rate of about 30 Å/min for about 5 minutes to produce a film with a thickness about 150 Å.

### Example 14

A 300 mm substrate has placed into the process chamber and maintained at about 550° C. at a pressure of about 10 Torr. A flow of process gas containing Ar (2,000 sccm) and BTBAS (25 sccm) was pulsed into the process chamber for 0.5 seconds. A layer of BTBAS was adsorbed to the substrate and the chamber was purged for 1 second to remove excess process gas. A flow of process gas containing Ar (1,000 sccm) and silane (500 sccm) was pulsed into the process chamber for 0.5 seconds. The BTBAS adsorbed to the substrate was chemically reduced to form a silicon nitride material on the substrate surface. The chamber was purged for 1 second to remove excess gasses, by-products and contaminates. The silicon nitride material was deposited at a rate of about 40 Å/min for about 5 minutes to produce a film with a thickness about 200 Å.

### Example 15

A 300 mm substrate has placed into the process chamber and maintained at about 550° C. at a pressure of about 10 Torr. A flow of process gas containing Ar (2,000 sccm) and BTBAS (25 sccm) was pulsed into the process chamber for 0.5 seconds. A layer of BTBAS was absorbed to the substrate and the chamber was purged for 1 second to remove excess process gas. A flow of process gas containing Ar (1,000 sccm) and disilane (500 sccm) was pulsed into the process chamber for 0.5 seconds. The BTBAS adsorbed to the substrate was chemically reduced to form a silicon nitride material on the substrate surface. The chamber was purged for 1 second to remove excess gasses, by-products and contaminates. The silicon nitride material was deposited at a rate of about 40 Å/min for about 5 minutes to produce a film with a thickness about 200 Å.

### Example 16

A 300 mm substrate has placed into the process chamber and maintained at about 600° C. at a pressure of about 10 Torr. A flow of process gas containing N₂ (2,000 sccm) and BTBAS (25 sccm) was pulsed into the process chamber for 0.5 seconds. A layer of BTBAS was adsorbed to the substrate and the chamber was purged for 1 second to remove excess process gas. A flow of process gas containing N₂ (1,000 sccm) and methane (500 sccm) was pulsed into the process chamber for 0.5 seconds. The BTBAS adsorbed to the substrate was chemically reduced to form a silicon nitride material on the substrate surface. The chamber was purged for 1 second to remove excess gasses, by-products and contaminates. The silicon nitride material was deposited at a rate of about 25 Å/min for about 5 minutes to produce a film with a thickness about 125 Å.

### Example 17

A 300 mm substrate has placed into the process chamber and maintained at about 550° C. at a pressure of about 10 Torr. A flow of process gas containing N₂ (2,000 sccm) and BTBAS (25 sccm) was pulsed into the process chamber for 0.5 seconds. A layer of BTBAS was adsorbed to the substrate and the chamber was purged for 1 second to remove excess process gas. A flow of process gas containing N₂ (1,000 sccm) and germane (500 sccm) was pulsed into the process chamber for 0.5 seconds. The BTBAS adsorbed to the substrate was chemically reduced to form a silicon nitride material on the substrate surface. The chamber was purged for 1 second to remove excess gasses, by-products and contaminates. The silicon nitride material was deposited at a rate of about 30 Å/min for about 5 minutes to produce a film with a thickness about 150 Å.

### Example 18

A 300 mm substrate has placed into the process chamber and maintained at about 550° C. at a pressure of about 10 Torr. A flow of process gas containing N₂ (2,000 sccm) and BTBAS (25 sccm) was pulsed into the process chamber for 0.5 seconds. A layer of BTBAS was adsorbed to the substrate and the chamber was purged for 1 second to remove excess process gas. A flow of process gas containing N₂ (1,000 sccm) and diborane (500 sccm) was pulsed into the process chamber for 0.5 seconds. The BTBAS adsorbed to the substrate was chemically reduced to form a silicon nitride material on the substrate surface. The chamber was purged for 1 second to remove excess gasses, by-products and contaminates. The silicon nitride material was deposited at a rate of about 40 Å/min for about 5 minutes to produce a film with a thickness about 200 Å.

While the foregoing is directed to embodiments of the invention, other and further embodiments of the invention may be devised without departing from the basic scope thereof, and the scope thereof is determined by the claims that follow.

1. A method for depositing a layer containing silicon nitride on a substrate surface, comprising:
positioning a substrate in a process chamber;
maintaining the substrate at a predetermined temperature;
exposing the substrate surface to an alkylaminosilane compound and at least one ammonia-free reactant; and
depositing a silicon nitride material on the substrate surface.

2. The method of claim 1, wherein the alkylaminosilane compound has a chemical formula of (RR′N)₄₋ₙSiHₙ, wherein R and R′ are independently selected from the group consisting of hydrogen, methyl, ethyl, propyl, butyl and pentyl and n=0, 1, 2 or 3.

3. The method of claim 2, wherein R is hydrogen and R′ is selected from the group consisting of methyl, ethyl, propyl, butyl and pentyl.

4. The method of claim 3, wherein R′ is butyl and n=2.

5. The method of claim 4, wherein the alkylaminosilane compound is bis(tertiarybutylamino)silane and the at least one ammonia-free reactant is hydrogen or silane.

6. The method of claim 2, wherein the at least one ammonia-free reactant is selected from the group consisting of H₂, SiH₄, Si₂H₆, GeH₄, CH₄, BH₃, B₂H₆, Et₃B, (H₃Si)₃N, Me₃N, Et₃N, H₂NNH₂, Me₂NNMe₂, derivatives thereof, and combinations thereof.

7. The method of claim 6, wherein the predetermined temperature is in a range from about 400° C. to about 650° C.

8. The method of claim 7, wherein the alkylaminosilane compound has a flow rate from about 1 sccm to about 100 sccm.

9. The method of claim 8, wherein the at least one ammonia-free reactant has a reactant flow rate of about 500 sccm or greater.

10. The method of claim 2, wherein the silicon nitride material has a N:Si atomic ratio from about 0.8 to about 1.3.

11. The method of claim 10, wherein the silicon nitride material has a carbon concentration from about 3 at % to about 15 at %.

12. A method for depositing a silicon nitride material on a substrate, comprising:
maintaining the substrate at a temperature in a range from about 400° C. to about 650° C. within a process chamber;
exposing the substrate to an alkylaminosilane compound and a reactant selected from the group consisting of hydrogen, silanes, boranes, germanes, alkyls, amines, hydrazines, derivatives thereof and combinations thereof.

13. The method of claim 12, wherein the alkylaminosilane compound has a chemical formula of (RR′N)₄₋ₙSiHₙ, wherein R and R′ are independently selected from the group consisting of hydrogen, methyl, ethyl, propyl, butyl and pentyl and n=0, 1, 2 or 3.

14. The method of claim 13, wherein R is hydrogen and R′ is selected from the group consisting of methyl, ethyl, propyl, butyl and pentyl.

15. The method of claim 14, wherein R′ is butyl and n=2.

16. The method of claim 15, wherein the alkylaminosilane compound is bis(tertiarybutylamino)silane and the reactant is hydrogen or silane.

17. The method of claim 13, wherein the reactant is selected from the group consisting of H₂, SiH₄, Si₂H₆, GeH₄, CH₄, BH₃, B₂H₆, Et₃B, (H₃Si)₃N, Me₃N, Et₃N, H₂NNH₂, Me₂NNMe₂, derivatives thereof, and combinations thereof.

18. The method of claim 17, wherein the alkylaminosilane compound has a flow rate from about 1 sccm to about 100 sccm.

19. The method of claim 18, wherein the reactant has a reactant flow rate of about 500 sccm or greater.

20. The method of claim 19, wherein the process chamber is a deposition chamber selected from the group consisting of chemical vapor deposition, thermal chemical vapor deposition and atomic layer deposition.

21. The method of claim 13, wherein the silicon nitride material comprises a N:Si atomic ratio from about 0.8 to about 1.3.

22. The method of claim 21, wherein the silicon nitride material has a carbon concentration from about 3 at % to about 15 at %.

23. A method for depositing a silicon nitride material on a substrate, comprising:
positioning a substrate in a process chamber;
maintaining the substrate at a predetermined temperature; and
exposing the substrate surface to bis(tertiarybutylamino)silane and at least one ammonia-free reactant.

24. The method of claim 23, wherein the silicon nitride material comprises a N:Si atomic ratio from about 0.8 to about 1.3.

25. The method of claim 24, wherein the silicon nitride material has a carbon concentration from about 3 at % to about 15 at %.

26. The method of claim 25, wherein the at least one ammonia-free reactant is selected from the group consisting of H₂, SiH₄, Si₂H₆, GeH₄, CH₄, BH₃, B₂H₆, Et₃B, (H₃Si)₃N, Me₃N, Et₃N, H₂NNH₂, Me₂NNMe₂, derivatives thereof, and combinations thereof.

27. The method of claim 26, wherein the bis(tertiarybutylamino)silane has a flow rate from about 1 sccm to about 100 sccm.

28. The method of claim 27, wherein the at least one ammonia-free reactant has a reactant flow rate of about 500 sccm or greater.

29. The method of claim 28, wherein the predetermined temperature is in a range from about 400° C. to about 650° C.

30. The method of claim 29, wherein the process chamber is a deposition chamber selected from the group consisting of chemical vapor deposition, thermal chemical vapor deposition and atomic layer deposition.

31. A method for depositing a silicon nitride material on a substrate, comprising:
positioning a substrate in a process chamber;
maintaining the substrate at a predetermined temperature; and
exposing the substrate surface to bis(tertiarybutylamino)silane and hydrogen gas.

32. The method of claim 31, wherein the silicon nitride material comprises a N:Si atomic ratio from about 0.8 to about 1.3.

33. The method of claim 32, wherein the silicon nitride material has a carbon concentration from about 3 at % to about 15 at %.

34. The method of claim 33, wherein the predetermined temperature is in a range from about 400° C. to about 650° C.

35. The method of claim 34, wherein the bis(tertiarybutylamino)silane has a flow rate from about 1 sccm to about 100 sccm.

36. The method of claim 35, wherein the hydrogen gas has a flow rate of about 500 sccm or greater.

37. The method of claim 36, wherein the process chamber is a deposition chamber selected from the group consisting of chemical vapor deposition, thermal chemical vapor deposition and atomic layer deposition.

38. A method for depositing a silicon nitride material on a substrate, comprising:
positioning a substrate in a process chamber;
maintaining the substrate at a predetermined temperature; and
exposing the substrate surface to bis(tertiarybutylamino)silane and silane or bis(tertiarybutylamino)silane and disilane.

39. The method of claim 38, wherein the silicon nitride material comprises a N:Si atomic ratio from about 0.8 to about 1.3.

40. The method of claim 39, wherein the silicon nitride material has a carbon concentration from about 3 at % to about 15 at %.

41. The method of claim 40, wherein the predetermined temperature is in a range from about 400° C. to about 650° C.

42. The method of claim 41, wherein the bis(tertiarybutylamino)silane has a flow rate from about 1 sccm to about 100 sccm.

43. The method of claim 42, wherein the silane or the disilane has a flow rate of about 500 sccm or greater.

44. The method of claim 43, wherein the process chamber is a deposition chamber selected from the group consisting of chemical vapor deposition, thermal chemical vapor deposition and atomic layer deposition.

45. A method for forming a device on a substrate surface, comprising:
depositing a gate material and a silicon nitride material on a substrate, wherein the silicon nitride material is deposited with a process, comprising:
positioning the substrate in a process chamber;
maintaining the substrate at a predetermined temperature; and
exposing the substrate surface to an ammonia-free process gas comprising an alkylaminosilane compound and at least one ammonia-free reactant.

46. A method for depositing a silicon nitride material on a substrate, comprising:
positioning a substrate in a process chamber;
maintaining the substrate at a predetermined temperature; and
exposing the substrate surface to bis(tertiarybutylamino)silane and a hydrocarbon or an alkyl compound.
